(19) United States
(12) Patent Application Publication
(10) Pub. No.: US 2012/0293240 A1
(43) Pub. Date: Nov. 22, 2012

(54) Membrane touch control panel

(76) Inventor: Chin-Hui Tseng Tsai, Zinbei City (TW)

(21) Appl. No.: 13/068,794

(22) Filed: May 19, 2011

(51) Int. Cl. H03K 17/96

(52) U.S. Cl. 327/517

(57) ABSTRACT

A membrane touch control panel includes a number of female conductors disposed on the basic layer and each having a number of electrodes electrically connected and coupled together, and each having an opening formed in each electrode, and a number of male conductors having a number of electrodes electrically connected and coupled together and received and engaged in the openings of the female electrodes respectively for forming a number of switch members, the membrane touch control panel includes a structure or configuration to be easily and quickly manufactured with greatly reduced manufacturing cost and procedures.

### BACKGROUND OF THE INVENTION

1. Field of the Invention

The present invention relates to a touch control panel, a touch switch, or a touch keyboard, and more particularly to a membrane touch control panel including a simplified structure for allowing the membrane touch control panel to be easily and quickly manufactured with greatly reduced manufacturing cost and procedures.

2. Description of the Prior Art

Typical touch control panels, touch switches, or touch keyboards comprise one or more key pad labels, and a pair of laminate sheets carry confronting conductor electrodes, each of the conductor electrodes being shaped to exactly follow the corresponding key pad label, and one or more spacer sheets disposed between the pair of laminate sheets for electrically separating the confronting conductor electrodes, and the spacer sheet is provided with a plurality of openings formed at positions corresponding to each of the conductor electrodes.

For example, U.S. Pat. No. 4,639,559 to Taguchi discloses one of the typical membrane keyboards also comprising a spacer sheet disposed between a pair of laminate sheets for electrically separating the confronting conductor electrodes, and arranged for allowing the confronting conductor electrodes to be selectively actuated and contacted with each other.

However, it will be complicated and difficult to attach or mount or secure or couple or anchor the laminate sheets and the spacer sheet and the key pad labels together, and to suitably align the confronting conductor electrodes of the laminate sheets with each other.

U.S. Pat. No. 5,901,834 to Inubushi et al. discloses another typical lighted switch illuminator comprising a stack consisting of the transparent electrode layer, a light emitting layer, a dielectric layer, a rear electrode layer, and a insulation layer arranged in an order and disposed between a printed board and a film click board which include the confronting conductor electrodes or contacts to be selectively actuated and contacted with each other.

However, it will be complicated and difficult to attach or mount or secure or couple or anchor the stack of the transparent electrode layer, and the light emitting layer, and the dielectric layer, and the rear electrode layer, and the insulation layer, and the printed board and the film click board together, and to suitably align the confronting conductor electrodes or contacts of the printed board and the film click board with each other.

The present invention has arisen to mitigate and/or obviate the afore-described disadvantages of the touch conventional membrane touch control panels.

### SUMMARY OF THE INVENTION

The primary objective of the present invention is to provide a membrane touch control panel including a simplified structure for allowing the membrane touch control panel to be easily and quickly manufactured with greatly reduced manufacturing cost and procedures.

In accordance with one aspect of the invention, there is provided a membrane touch control panel comprising a basic layer, a number of first conductors provided on the basic layer, and each first conductor including a number of first electrodes electrically connected and coupled together, and each first conductor including an opening formed in each of the first electrodes, and a number of second conductors provided on the basic layer, and each second conductor including a number of second electrodes electrically connected and coupled together, and the second electrodes of the second conductors being received and engaged in the openings of the first electrodes respectively for forming a number of switch members, in which the membrane touch control panel includes a structure or configuration that may be easily and quickly manufactured with greatly reduced manufacturing cost and procedures.

A control device may further be provided, and the first conductors and the second conductors are electrically connected and coupled to the control device. The switch members are preferably arranged in a matrix.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a top plan schematic view of a membrane touch control panel in accordance with the present invention, illustrating the operation of the membrane touch control panel;

FIG. 2 is a perspective view of the membrane touch control panel;

FIG. 3 is a top plan schematic view of the membrane touch control panel;

FIG. 4 is a front or side plan schematic view of the membrane touch control panel; and

FIG. 5 is another top plan schematic view similar to FIG. 3, illustrating the other arrangement of the membrane touch control panel.

### DETAILED DESCRIPTION OF THE PREFERRED EMBODIMENT

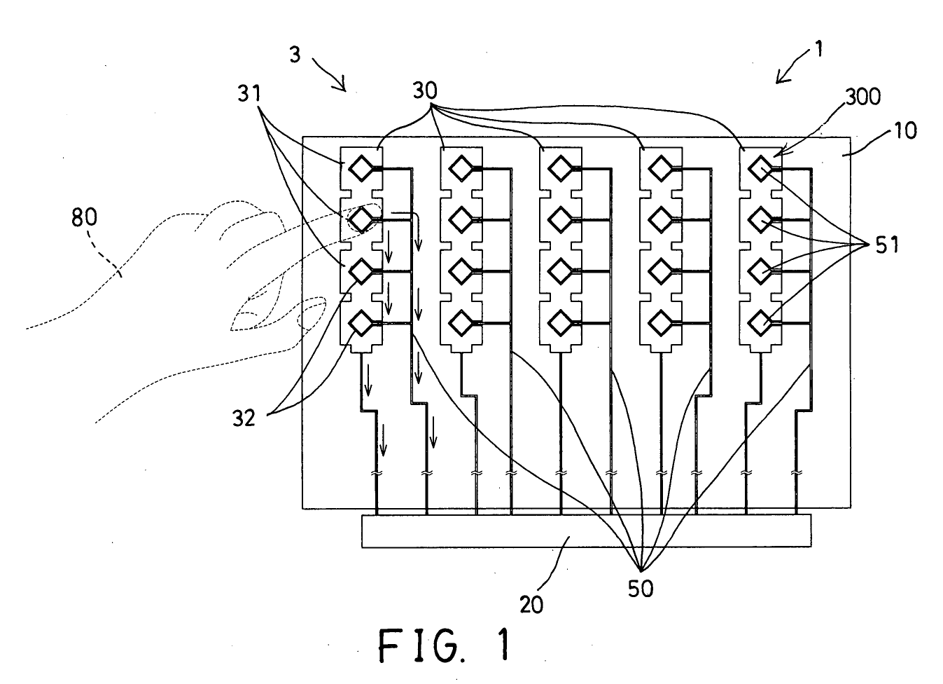

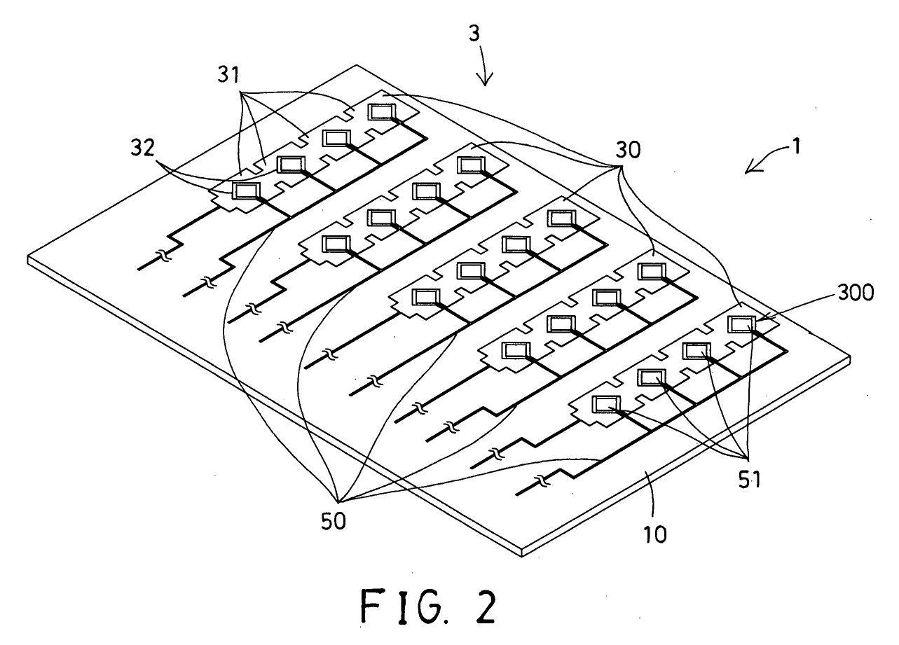

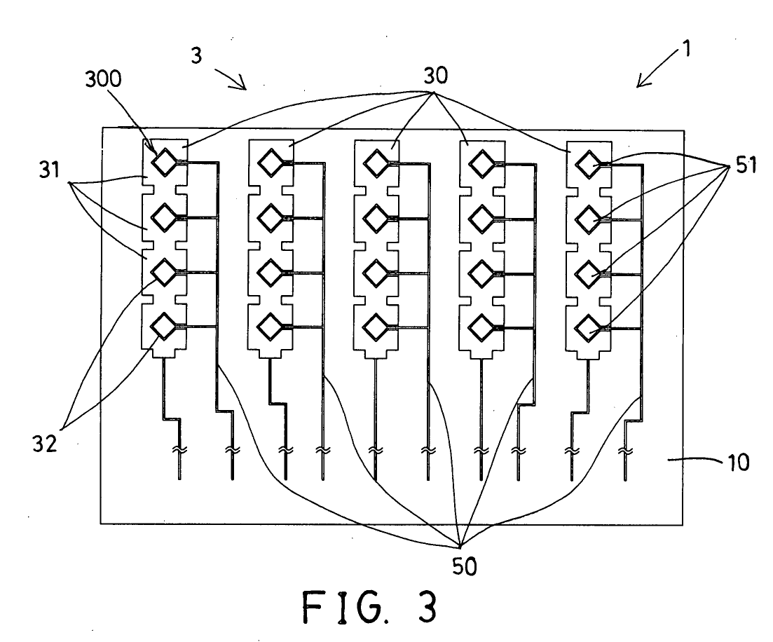

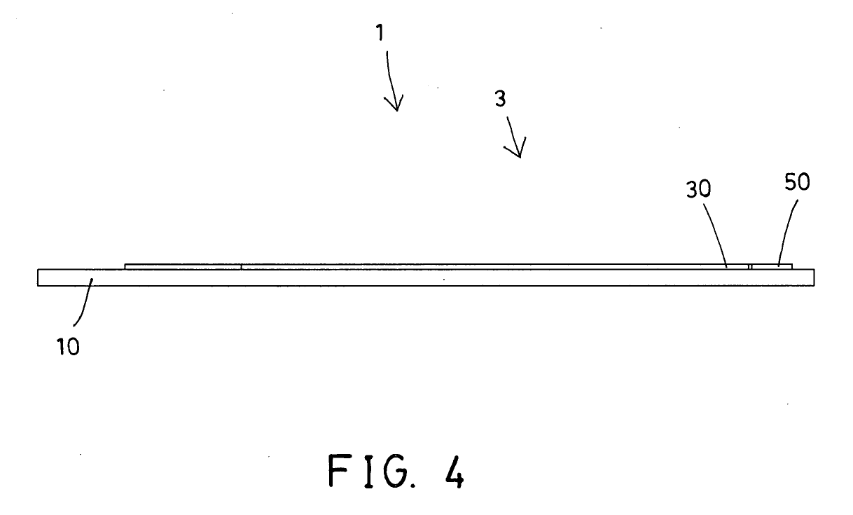

Referring to the drawings, and initially to FIGS. 1-4, a membrane touch control panel 1 in accordance with the present invention comprises a basic board or panel or sheet or layer 10, and a microprocessor or processing member or control device 20 disposed or located beside the basic layer 10, and a switch device 3 including a number of first conductors 30 and a number of second conductors 50 disposed or attached or applied or mounted or provided or secured or printed on the basic layer 10, and the first conductors 30 includes a number of first electrodes 31 electrically connected or coupled together, and the second conductors 50 also includes a number of second electrodes 51 electrically connected or coupled together and to be selectively actuated or caused to electrically contact with the first electrodes 31 of the first conductors 30.

The first conductors 30 includes a notch or cavity or opening 32 formed in each of the first electrodes 31 for receiving or engaging with the second electrodes 51 of the second conductors 50 respectively, in which the first electrodes 31 of the first conductors 30 and the second electrodes 51 of the second conductors 50 are located in the same plane or height, and the second electrodes 51 of the second conductors 50 are located or engaged in the openings 32 of the first electrodes 31 for forming a number of switch members 300, such that the first electrodes 31 of the first conductors 30 and the second electrodes 51 of the second conductors 50 may be easily and quickly disposed or attached or applied or mounted or secured or printed on the basic layer 10 with a greatly simplified printing or applying or manufacturing procedure. The first conductors 30 and the second conductors 50 are electrically connected or coupled to the control device 20.

In operation, as shown in FIG. 1, either of the first electrodes 31 of the first conductors 30 and the second electrodes 51 of the second conductors 50, or either of the switch members 300 may be depressed or actuated or contacted by the finger of the user 80, and the respective electrodes 31, 51 of the conductors 30, 50 may be electrically connected or coupled together with the finger of the user 80, and may then send a corresponding signal to the control device 20 which may detect and determine which of the switch members 300 has been depressed or actuated or contacted by the finger of the user 80. It is preferable that the switch members 300 or the respective electrodes 31, 51 of the conductors 30, 50 are arranged in a matrix or the like.

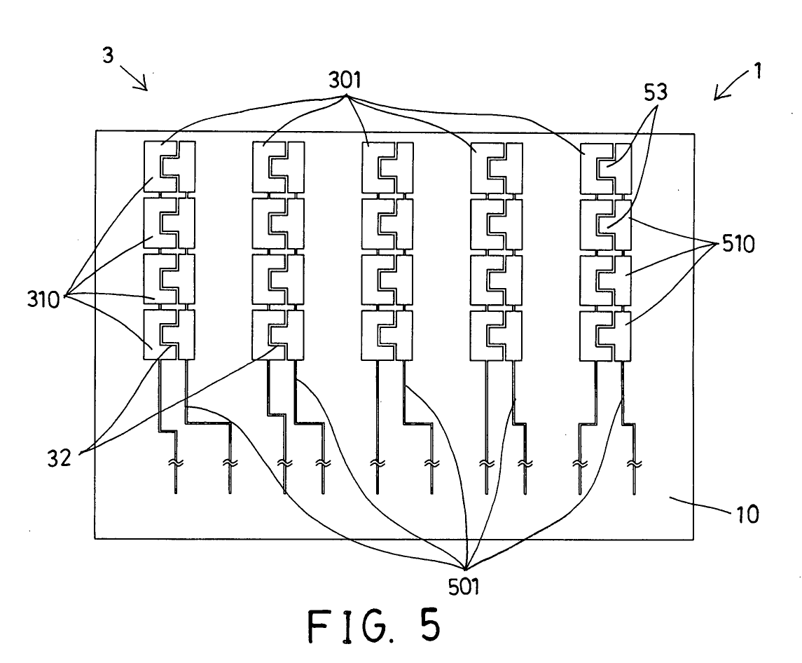

Alternatively, as shown in FIG. 5, the first conductors 301 also includes a notch or cavity or opening 32 formed in each of the first electrodes 310 for receiving or engaging with a projection 53 of each of the second electrodes 510 of the second conductors 501 respectively, in which the first electrodes 310 of the first conductors 301 and the second electrodes 510 of the second conductors 501 are also located in the same plane or height, and the second electrodes 510 of the second conductors 501 are located or engaged in the openings 32 of the first electrodes 310 for forming a number of switch members; i.e., the openings 32 of the first electrodes 310 may be formed in various kinds of shapes or contours for receiving or engaging with the projections 53 of the second electrodes 510 of the second conductors 501 having corresponding shapes or contours.

It is to be noted that the structure or configuration of the membrane touch control panel may be greatly simplified and may be easily and quickly manufactured with greatly reduced manufacturing cost, and the manufacturing procedures for the membrane touch control panel may also be greatly simplified or reduced.

Accordingly, the membrane touch control panel in accordance with the present invention includes a simplified structure for allowing the membrane touch control panel to be easily and quickly manufactured with greatly reduced manufacturing cost and procedures.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A membrane touch control panel comprising:
a basic layer,
a plurality of first conductors provided on said basic layer, and each first conductor including a plurality of first electrodes electrically connected and coupled together, and each first conductor including an opening formed in each of said first electrodes, and
a plurality of second conductors provided on said basic layer, and each second conductor including a plurality of second electrodes electrically connected and coupled together, and said second electrodes of said second conductors being received and engaged in said openings of said first electrodes respectively for forming a plurality of switch members.

2. The membrane touch control panel as claimed in claim 1 further comprising a control device, said first conductors and said second conductors are electrically connected and coupled to said control device.

3. The membrane touch control panel as claimed in claim 1, wherein said switch members are arranged in a matrix.
